(19) United States
(12) Patent Application Publication
(10) Pub. No.: US 2017/0133625 A1
(43) Pub. Date: May 11, 2017

(54) Packaging Assembly and Packaging Method Thereof, and OLED Apparatus

(71) Applicant: BOE Technology Group Co., Ltd., Beijing (CN)

(72) Inventor: Yi Li, Beijing (CN)

(73) Assignee: BOE Technology Group Co., Ltd., Beijing (CN)

(21) Appl. No.: 15/321,856

(22) PCT Filed: Apr. 14, 2016
(86) PCT No.: PCT/CN2016/079270

§ 371 Date: Dec. 23, 2016

(30) Foreign Application Priority Data
Jun. 8, 2015 (CN) 201510312061.6

(51) Int. Cl. H01L 51/52; H01L 51/56

(52) U.S. Cl. CPC H01L 51/5246; H01L 51/56

(57) ABSTRACT

A package, a packaging method thereof and an organic light-emitting diode (OLED) device are provided. The packaging assembly includes a first substrate and a second substrate which are arranged oppositely; a first sealing structure arranged between the first substrate and the second substrate, wherein the first sealing structure the first substrate and the second substrate enclose to form a first cavity; and a second sealing structure arranged between the first substrate and the second substrate, wherein the second sealing structure is positioned on the outer side of the first sealing structure and encloses a second cavity together with the first sealing structure, the first substrate and the second substrate.

### TECHNICAL FIELD

The present disclosure relates to a package, a packaging method thereof and an organic light-emitting diode (OLED) device.

### BACKGROUND

OLED is widely applied in display technology due to the advantages of self luminescence, rapid response, wide viewing angle, high brightness, bright color, light weight, etc.

An OLED device package technology is to adopt glass frit package process. As illustrated in FIG. 1, in an OLED device, an OLED structure 03 is disposed between a glass cover plate 01 and a glass backplane 02. The OLED main structure specifically includes an organic emission functional layer, etc. As the organic emission functional layer will produce irreversible photo-oxidation reaction in the presence of moisture and oxygen, in order to ensure the sealability of the OLED device, after the glass cover plate 01 is aligned to and bonded with the glass backplane 02, glass frit is fused by laser to form a frit sealing layer 04, and hence the OLED device is packaged.

However, as most glass frit used in the frit package process is hard material, the OLED device has poor shock resistance and compressive property, and hence the mechanical property of the entire OLED device can be affected.

### SUMMARY

An embodiment of the disclosure provides a package, comprising: a first substrate and a second substrate arranged opposite to each other; a first sealing structure disposed between the first substrate and the second substrate, a first cavity being encircled by the first sealing structure, the first substrate and the second substrate; and a second sealing structure disposed between the first substrate and the second substrate, the second sealing structure being disposed on an outer side of the first sealing structure, and a second cavity being encircled by the second sealing structure, the first sealing structure, the first substrate and the second substrate.

Another embodiment of the disclosure provides an organic light-emitting diode (OLED) device, comprising: the package as mentioned above, and an OLED structure disposed in the first cavity of the package.

Another embodiment of the disclosure provides a packaging method, comprising: coating UV adhesive on a first substrate provided with sintered glass frit, the glass frit being disposed in a first sealing area of the first substrate; the UV adhesive being disposed in a second sealing area of a second substrate; the second sealing area is disposed on an outer side of the first sealing area; aligning and bonding the first substrate and a second substrate provided with an OLED structure; and forming a first sealing structure in the first sealing area between the first substrate and the second substrate, and forming a second sealing structure in the second sealing area, wherein a first cavity is encircled by the first sealing structure, the first substrate and the second substrate; the second sealing structure is disposed on an outer side of the first sealing structure; and a second cavity is encircled by the second sealing structure, the first sealing structure, the first substrate and the second substrate.

### BRIEF DESCRIPTION OF THE DRAWINGS

Simple description will be given below to the accompanying drawings of the embodiments to provide a more clear understanding of the technical proposals of the embodiments of the present invention. Obviously, the drawings described below only involve some embodiments of the present invention but are not intended to limit the present invention.

FIG. 1 is a schematic structural view of a packaged OLED device;

FIG. 2a is a first sectional view of a package provided by the embodiment of the present disclosure;

FIG. 2b is a top view of the package provided by the embodiment of the present disclosure;

FIG. 3 is a second sectional view of a package provided by the embodiment of the present disclosure;

FIG. 4 is a third sectional view of a package provided by the embodiment of the present disclosure;

FIG. 5 is a first flowchart of a packaging method provided by the embodiment of the present disclosure; and

FIG. 6 is a second flowchart of the packaging method provided by the embodiment of the present disclosure.

### DETAILED DESCRIPTION

For more clear understanding of the objectives, technical proposals and advantages of the embodiments of the present invention, clear and complete description will be given below to the technical proposals of the embodiments of the present invention with reference to the accompanying drawings of the embodiments of the present invention. Obviously, the preferred embodiments are only partial embodiments of the present invention but not all the embodiments. All the other embodiments obtained by those skilled in the art without creative efforts on the basis of the embodiments of the present invention illustrated shall fall within the scope of protection of the present invention.

The foregoing description, for purposes of illustration and not limitation, put forwards specific details such as specific system structures, interfaces and technology for more clear understanding of the present invention. However, it should be understood by those skilled in the art that the present invention could also be achieved in other embodiments not provided with the specific details. In other cases, the detailed description of well-known devices, circuits and methods is omitted, so unnecessary details cannot hinder the description of the present invention.

In addition, the terms “first” and “second” are only used for describing the objective and should not be construed as the indication or implication of the relative importance or the implication of the number of the indicated technical characteristics. Thus, the characteristic defined by “first” and “second” may indicate or imply that one or more characteristics are included. In the description of the present invention, unless otherwise specified, “a plurality of” means two or more than two.

As illustrated in FIGS. 2a and 2b, the embodiment of the present disclosure provides a package 100 (in which FIG. 2a is a sectional view of the package 100 and FIG. 2b is a top view of the package 100). The package 100 comprises a first substrate 101 and a second substrate 102 arranged opposite to each other; and a first sealing structure 103 disposed between the first substrate 101 and the second substrate 102. A first cavity 200 is encircled by the first sealing structures 103, the first substrate 101 and the second substrate 102 and may be configured to place an OLED structure. The OLED structure herein may be a whole structure of an OLED or one part of the OLED, e.g., an organic emission functional layer, a hole transport layer (HTL) and an electron transport layer (ETL). The layers may also be referred to as a main structure of the OLED.

A second sealing structures 104 is further disposed between the first substrate 101 and the second substrate 102. The second sealing structure 104 is disposed on the outer side of the first sealing structure 103. A second cavity 300 is encircled by the second sealing structures 104, the first sealing structures 103, the first substrate 101 and the second substrate 102. The second cavity can reduce the impact on the first sealing structures 103.

In addition, it should be noted that: in order to further reduce the impact on the first sealing structures 103, a plurality of second cavities 300 can be disposed between the first substrate 101 and the second substrate 102. No limitation will be given here in the present invention.

As can be seen, as the second cavity 300 is formed between the first sealing structure 103 and the second sealing structure 104 in the package 100 and is configured to reduce the impact on the first sealing structure 103, the second cavity 300 may be taken as a buffer layer between the first sealing structure 103 and the second sealing structure 104, so the external impact on package materials in the first cavity 200 can be reduced as much as possible, and hence the shock resistance and the compressive property of the entire package 100 can be improved.

For instance, as illustrated in FIG. 2, both sections of the first sealing structure 103 and the second sealing structure 104 in parallel to the first substrate are of an annular shape. Thus, the first sealing structure 103 and the second sealing structure 104 may be matched with the first substrate and the second substrate to form the first cavity and the second cavity.

The first cavity 200 may be provided with an OLED main structure such as a hole transportation layer (HTL), an organic emission layer (EML) and an electron transportation layer (ETL) of an OLED device. As the OLED main structure will produce irreversible photo-oxidation reaction in the presence of moisture and oxygen, multiple sealing structures in the package 100 can prevent moisture and oxygen from entering the OLED main structure. Meanwhile, the shock resistance and the compressive property of the package 100 can be improved by the buffer layers between the first sealing structures 103 and the second sealing structures 104.

Moreover, the second cavity 300 is filled with a foaming agent and/or an organic adhesive.

The foaming agent is a surface active substance and mainly has the functions of reducing the interfacial tension on a gas-water interface, promoting the formation of small air bubbles in paste, expanding a separation interface, and ensuring that the air bubbles rise to form a foam layer. The organic adhesive refers to a compound containing Si—C bond, in which at least one organic group is directly attached to silicon atoms. Both the organic adhesive and the foaming agent with low elastic modulus may be taken as effective buffer material. Therefore, when the foaming agent and/or the organic adhesive is filled into the second cavity 300, the buffer effect of the buffer layers between the first sealing structures 103 and the second sealing structures 104 can be increased, and hence the shock resistance and the compressive property of the package 100 can be further improved.

Moreover, a drying agent, e.g., water and oxygen reactive substances such as calcium sulfate, may also be added in the foaming agent and/or the organic adhesive. Thus, an effective protective layer may be formed on the periphery of the package materials in the first cavity 200, and moisture and oxygen can be prevented from entering the package materials.

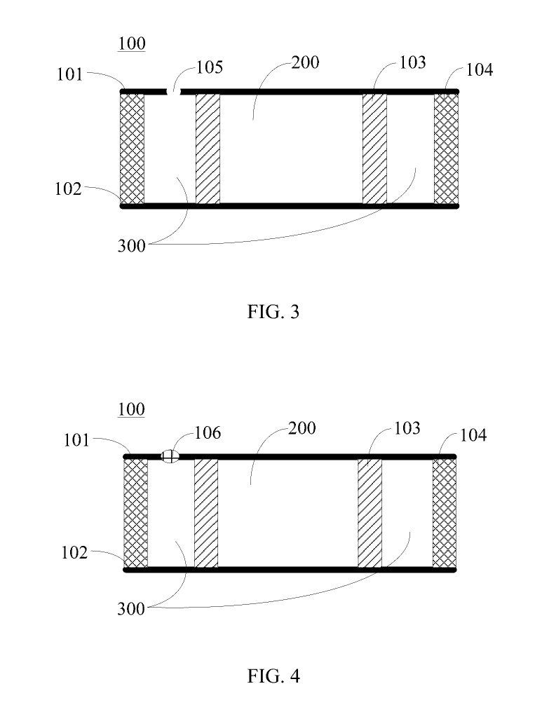

Illustratively, based on the package 100 as illustrated in FIGS. 2a and 2b, as illustrated in FIG. 3 (FIG. 3 is a sectional view of the package 100), the first substrate 101 is also provided with a connecting hole 105 communicated with the second cavity 300. Thus, the foaming agent and/or the organic adhesive may be injected into the second cavity 300 through the connecting hole 105.

Moreover, based on the package 100 as shown in FIG. 3, as illustrated in FIG. 4 (FIG. 4 is a sectional view of the package 100), the connecting hole 105 may also be provided with a filling fused mass (fusible body) 106. The fusible body 106 is a glass mixture for absorbing microwave or laser and may be configured to seal the connecting hole 105. Thus, after the foaming agent and/or the organic adhesive is injected into the second cavity 300, the fusible body 106 on the connecting hole 105 may be heated by laser or microwave, so that the fusible body 106 can be heated and fused to package the connecting hole 105. The heat-affected zone of the package process is small, and excessive residual stress will not be produced to result in the warping of the first substrate 101.

In addition, the first sealing structure 103 in the package 100 may be specifically a sealing structure formed by the sintering, laser scanning and curing of glass frit via frit package process, and the second sealing structure 104 in the package 100 may be specifically a sealing structure formed by the curing of UV adhesive via UV package process, namely cured UV adhesive. The sealing structure formed by the frit package process has high moisture and oxygen resistance and poor mechanical property, and the UV package process is relative simple. Therefore, the package 100 provided with multiple sealing structures formed by the above processes can simplify the manufacturing process and improve the moisture and oxygen resistance of the package 100 as much as possible.

The embodiment of the present disclosure provides a package, which comprises a first substrate and a second substrate arranged opposite to each other, wherein first sealing structure is disposed between the first substrate and the second substrate; a first cavity is encircled by the first sealing structure, the first substrate and the second substrate and configured to place an OLED main structure; a second sealing structure is also disposed between the first substrate and the second substrate; the second sealing structure is disposed on the outer side of the first sealing structure; and a second cavity is encircled by the second sealing structure, the first sealing structure, the first substrate and the second substrate and may be configured to reduce the impact on the first sealing structures. Thus, the second cavity may be taken as a buffer layer between the first sealing structure and the second sealing structure, so that the external impact on the OLED main structure in the first cavity can be reduced as much as possible, and hence the shock resistance and the compressive property of the entire package can be improved.

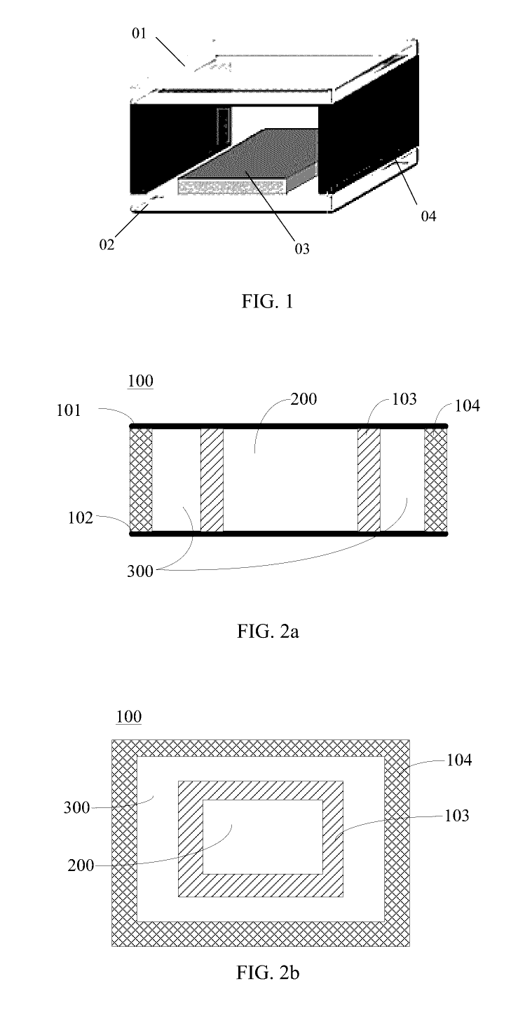

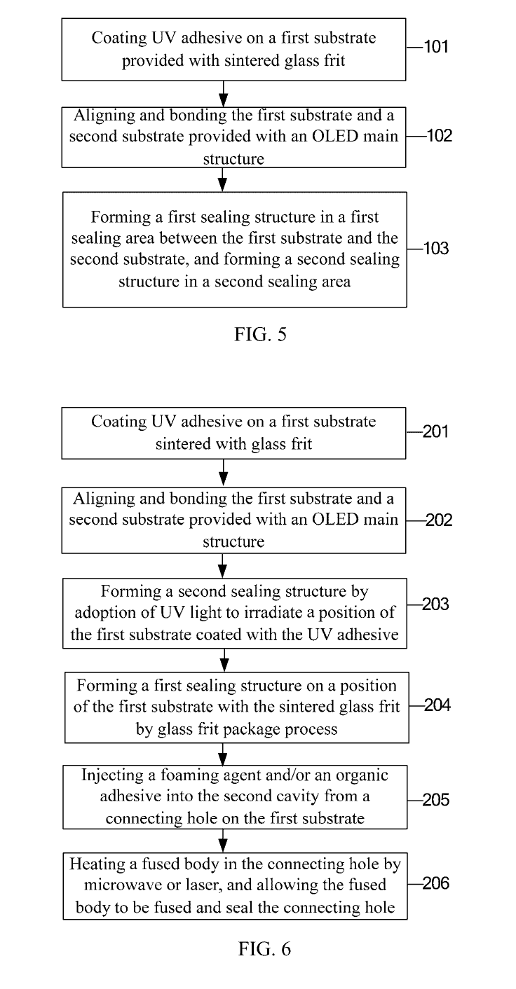

FIG. 5 illustrates a packaging method provided by the embodiment of the present disclosure. The packaging method provided by the embodiment of the present disclosure is used for manufacturing the package 100 as illustrated in FIGS. 1 to 4. For convenient description, only those relevant to the embodiment of the present disclosure are illustrated. The specific technical details which are not indicated refer to the embodiments of the present disclosure as shown in FIGS. 1 to 4.

For instance, taking an OLED device as an example, the packaging method comprises:

101: coating UV adhesive on a first substrate provided with sintered glass frit.

The OLED device, for instance, includes a first substrate and a second substrate provided with an OLED main structure. When the OLED device is packaged, the first substrate and the second substrate must be aligned and bonded before package, so that the OLED main structure in the OLED device can be disposed in a moisture and oxygen resistant enclosed space.

The glass frit is disposed in a first sealing area of the first substrate; the UV adhesive is disposed in a second sealing area of the second substrate; and the second sealing area is disposed on the outer side of the first sealing area.

For instance, the first sealing area to be packaged of the first substrate may be coated with the glass frit by screen printing; subsequently, the first substrate coated with the glass frit is placed in a sintering furnace for sintering; and finally, UV adhesive is coated on the second sealing area of the sintered first substrate, in which the UV adhesive may be cured when irradiated under UV light and used as an adhesive.

S102: aligning and bonding the first substrate and the second substrate provided with the OLED main structure.

S103: forming a first sealing structure in the first sealing area between the first substrate and the second substrate, and forming a second sealing structure in the second sealing area.

A first cavity is encircled by the first sealing structure, the first substrate and the second substrate; the second sealing structure is disposed on the outer side of the first sealing structure; and a second cavity is encircled by the second sealing structures, the first sealing structures, the first substrate and the second substrate.

For instance, the first substrate and the second substrate may be subjected to first package to form the second sealing structure by adoption of UV light to irradiate a position of the first substrate coated with the UV adhesive (namely the second sealing area) via UV package process; and a position of the first substrate sintered with the glass frit (namely the first sealing area) is subjected to second package to form the first sealing structures by frit package process.

As illustrated in FIG. 2a or 2b, a first cavity is encircled by the first sealing structure, the first substrate and the second substrate; and a second cavity is encircled by the first sealing structure, the second sealing structure, the first substrate and the second substrate. The second cavity may be taken as a buffer layer between the first sealing structure and the second sealing structure, so that the external impact on the OLED main structure in the first cavity can be reduced as much as possible, and hence the shock resistance and the compressive property of the entire package can be improved.

Illustratively, the first substrate may also be provided with a connecting hole communicated with the second cavity, and the connecting hole is also provided with a fusible body, in which the fusible body is a glass mixture for absorbing microwave or laser. At this point, the embodiment of the present disclosure provides a packaging method, which, as illustrated in FIG. 6, specifically comprises:

201: coating UV adhesive on a first substrate sintered with glass frit.

Specifically, a first sealing area of the first substrate may be coated with the glass frit by screen printing process according to a predetermined pattern on a screen; subsequently, the first substrate coated with the glass frit is placed in a sintering furnace for sintering; and finally, the UV adhesive is coated on a second sealing area of the sintered first substrate.

202: aligning and bonding the first substrate and a second substrate provided with an OLED main structure.

203: forming a second sealing structure by adoption of UV light to irradiate a position of the first substrate coated with the UV adhesive.

As the UV adhesive may be cured when irradiated under UV light and taken as an adhesive, the UV light may be adopted to irradiate the position of the first substrate coated with the UV adhesive by UV package process, and the formed first sealing structures are respectively bonded to the first substrate and the second substrate.

204: forming a first sealing structure on a position of the first substrate sintered with the glass frit by glass frit package process.

For instance, the first sealing structures are formed by the laser scanning of the position of the first substrate sintered with the glass frit by the frit package process, in which a gap is formed between the first sealing structure and the second sealing structure in 5203. Thus, the second sealing structure is respectively bonded to the first sealing structure, the first substrate and the second substrate to form the second cavity.

S205: injecting a foaming agent and/or an organic adhesive into the second cavity from a connecting hole on the first substrate.

As the penetrable connecting hole is preformed on the first substrate, the foaming agent and/or the organic adhesive may be injected in the second cavity through the connecting hole. As both the organic adhesive and the foaming agent may be taken as an effective buffer material, when the foaming agent and/or the organic adhesive is filled into the second cavity, the buffer effect of the buffer layer between the first sealing structure and the second sealing structure can be increased, and hence the shock resistance and the compressive property of the package can be further improved.

In addition, a drying agent, e.g., water and oxygen reactive substances such as calcium sulfate, may also be added in the foaming agent and/or the organic adhesive. Thus, an effective protective layer may be formed on the periphery of the OLED main structure in the first cavity, and moisture and oxygen can be prevented from entering the OLED main structure.

206: heating filling fused mass on the connecting hole by microwave or laser, and allowing the filling fused mass to be fused and seal the connecting hole.

Finally, after the foaming agent and/or the organic adhesive is injected into the second cavity, the filling fused mass on the connecting hole may be heated by laser or microwave, so that the filling fused mass can be heated and fused to package the connecting hole. The heat-affected zone of the package process is small, and excessive residual stress cannot be produced to result in the warping of the first substrate.

The embodiment of the present disclosure provides a packaging method, wherein a first sealing structure is disposed between a first substrate and a second substrate which are arranged opposite to each other; a first cavity is encircled by the first sealing structure, the first substrate and the second substrate and configured to place an OLED main structure; a second sealing structure is further disposed between the first substrate and the second substrate; the second sealing structure is disposed on the outer side of the first sealing structure; and a second cavity is encircled by the second sealing structure, the first sealing structure, the first substrate and the second substrate and may be configured to reduce the impact on the first sealing structures. Thus, the second cavity may be taken as a buffer layer between the first sealing structure and the second sealing structure, so that the external impact on the OLED main structure in the first cavity can be reduced as much as possible, and hence the shock resistance and the compressive property of the entire package can be improved.

Moreover, the embodiment of the present disclosure further provides an OLED device, which specifically comprises the package 100 provided by the embodiment, and an OLED main structure disposed in the first cavity 200 of the package 100, wherein the OLED main structure may specifically includes an HTL, an organic EML or an HTL of the OLED device. As the OLED main structure will produce irreversible photo-oxidation reaction in the presence of moisture and oxygen, the multiple sealing structures in the package 100 can prevent moisture and oxygen from entering the OLED main structure. Meanwhile, the shock resistance and the compressive property of the package 100 can be improved by the buffer layers between the first sealing structures 103 and the second sealing structures 104.

In the description, the specific characteristics, structures, materials or features may be combined properly in any one or more embodiments or examples.

The foregoing is only the preferred embodiments of the present invention and not intended to limit the scope of protection of the present invention. The scope of protection of the present invention should be defined by the appended claims.

The application claims priority to the Chinese patent application No. 201510312061.6, filed Jun. 8, 2015, the disclosure of which is incorporated herein by reference as part of the application.

1. A package, comprising:
a first substrate and a second substrate arranged opposite to each other;
a first sealing structure disposed between the first substrate and the second substrate, a first cavity being encircled by the first sealing structure, the first substrate and the second substrate; and
a second sealing structure disposed between the first substrate and the second substrate, the second sealing structure being disposed on an outer side of the first sealing structure, and a second cavity being encircled by the second sealing structure, the first sealing structure, the first substrate and the second substrate.

2. The package according to claim 1, wherein the second cavity is filled with at least one of a foaming agent or an organic adhesive.

3. The package according to claim 2, wherein at least one of the foaming agent or the organic adhesive contains a drying agent.

4. The package according to claim 2, wherein the first substrate is further provided with a connecting hole communicated with the second cavity; and the connecting hole is configured to inject at least one of the foaming agent or the organic adhesive.

5. The package according to claim 4, wherein the connecting hole is also provided with a fusible body which is configured to seal the connecting hole.

6. The package according to claim 5, wherein the fusible body is glass mixture for absorbing microwave or laser.

7. The package according to claim 1, wherein the first sealing structure is formed by sintering, laser scanning and curing of glass frit.

8. The package according to claim 1, wherein the second sealing structure is cured UV adhesive.

9. The package according to claim 1, wherein both sections of the first sealing structure and the second sealing structure in parallel to the first substrate are of an annular shape.

10. An organic light-emitting diode (OLED) device, comprising: the package according to claim 1, and an OLED structure disposed in the first cavity of the package.

11. A packaging method, comprising:
coating UV adhesive on a first substrate provided with sintered glass frit, the glass frit being disposed in a first sealing area of the first substrate; the UV adhesive being disposed in a second sealing area of the first substrate; the second sealing area is disposed on an outer side of the first sealing area;
aligning and bonding the first substrate and a second substrate provided with an OLED structure; and
forming a first sealing structure in the first sealing area between the first substrate and the second substrate, and forming a second sealing structure in the second sealing area, wherein a first cavity is encircled by the first sealing structure, the first substrate and the second substrate; the second sealing structure is disposed on an outer side of the first sealing structure; and a second cavity is encircled by the second sealing structure, the first sealing structure, the first substrate and the second substrate.

12. The method according to claim 11, wherein in the aligning and bonding process, a side of the first substrate provided with the glass frit and the UV adhesive faces a side of the second substrate provided with the OLED structure.

13. The method according to claim 11, wherein both the first sealing area and the second sealing area are of an annular shape.

14. The method according to claim 11, wherein forming the first sealing structure and the second sealing structure between the first substrate and the second substrate includes:
adopting UV light to irradiate a position of the first substrate coated with the UV adhesive, and forming the second sealing structure by curing the UV adhesive; and
forming the first sealing structure by the sintered glass frit on the first substrate by a glass frit package process.

15. The method according to claim 14, wherein the first substrate is provided with a connecting hole communicated with the second cavity; and
after forming the first sealing structure by the sintered glass frit on the first substrate by the glass frit package process, the method further comprises:
injecting a foaming agent and/or an organic adhesive into the second cavity from the connecting hole.

16. The method according to claim 15, wherein after injecting the foaming agent and/or the organic adhesive into the second cavity from the connecting hole, the method further comprises:
arranging a fusible body in the connecting hole, heating the fusible body by microwave or laser, and allowing the fusible body to fuse and seal the connecting hole.

17. The package according to claim 3, wherein the first substrate is further provided with a connecting hole communicated with the second cavity; and the connecting hole is configured to inject at least one of the foaming agent or the organic adhesive.

18. The package according to claim 2, wherein the first sealing structure is formed by sintering, laser scanning and curing of glass frit.

19. The package according to claim 2, wherein the second sealing structure is cured UV adhesive.

20. The package according to claim 2, wherein both sections of the first sealing structure and the second sealing structure in parallel to the first substrate are of an annular shape.
